(19) United States
(12) Patent Application Publication
(10) Pub. No.: US 2006/0039115 A1
(43) Pub. Date: Feb. 23, 2006

(54) Pre-fastened heat sink clip

(76) Inventor: Jason Muroki, Irvine, CA (US)

Correspondence Address: ORRICK, HERRINGTON & SUTCLIFFE, LLP;IP PROSECUTION DEPARTMENT, 4 PARK PLAZA, SUITE 1600, IRVINE, CA, 92614-2558, US

(21) Appl. No.: 10/922,236

(22) Filed: Aug. 18, 2004

(51) Int. Cl. H05K 7/20

(52) U.S. Cl. 361/704

(57) ABSTRACT

Apparatus and methods are provided that facilitate installation and removal of integrated circuits (“IC”) and other components from a heat sink in consumer electronics systems. Preferably, a clip is provided pre-fastened at one end to a heat sink. The other unfastened end of the clip is adapted to be releasably latched in place on the heat sink to retain the IC or other component needing heat dissipation in place once it has been positioned against the heat sink as desired. Preferably, the clip comprises a thin spring-like body including an upper cross member extending between first and second legs, which extend generally orthogonally from the cross member. The cross-member preferably curves inwardly toward the space between the legs and presses against the IC or other component with a spring-like force to ensure good thermal transfer from the IC or other component to the heat sink. The second leg is preferably adapted to releasably engage a slot or other receptacle formed in the body of the heat sink. Extending outwardly generally orthogonally from the fixed leg is a mounting base to secure or pre-fasten one end of the clip to the heat sink. Alternatively, the clip may be integrally formed with the heat sink with the fixed leg extending from-the heat sink.

### FIELD OF THE INVENTION

The invention relates generally to heat sinks for consumer electronic systems such as televisions and, more particularly, to an apparatus and methods that facilitate the installation and removal integrated circuits and other components from a heat sink.

### BACKGROUND INFORMATION

Consumer electronic devices such as televisions and the like, tend to utilize integrated circuits (ICs) and other components that require heat dissipation. To facilitate heat dissipation, these systems typically include heat sinks secured to a chassis or IC board at appropriate locations with the ICs or other components needing heat dissipation mounted on the heat sinks. Because the ICs and other components are typically mounted to the heat sinks using screws, lock washers, bolts and the like, the installation and removal these components fastened to the heat sinks tends to be time consuming and cumbersome.

Accordingly, it would be desirable to provide apparatuses and methods that facilitate the installation and removal of integrated circuits and other components on heat sinks in consumer electronic devices.

### SUMMARY

The present invention is directed to apparatuses and methods that facilitate the installation and removal of integrated circuits and other components on heat sinks with consumer electronic devices. In a preferred embodiment, a clip is provided pre-fastened at one end to a heat sink. The other unfastened end of the clip is adapted to be releasably latched in place on the heat sink to retain the IC or other component needing heat dissipation in place once it has been positioned against the heat sink as desired. Preferably, the clip comprises a thin body formed from steel, half hardness steel, or other metals, plastics, composites, or the like, and has an upper cross member extending between a fixed leg and an latching leg, which extend generally orthogonally from the cross member. The cross-member preferably curves inwardly toward the space between the legs and presses against the IC or other component with a spring-like force to ensure good thermal transfer from the IC or other component to the heat sink. The latching leg is preferably adapted to releasably engage a slot or other receptacle formed in the body of the heat sink. Extending outwardly generally orthogonally from the fixed leg end is a mounting base to secure or pre-fasten one end of the clip to the heat sink.

In operation, the mounting base is fastened to the heat sink to pre-fasten the clip in place prior to installation. The heat sink is then fastened to the chassis of an electronic device in an appropriate location. Once an IC or other component is positioned against the heat sink as desired, the unfastened latching leg is pushed and latched into place retaining the IC or other component against the heat sink without the use of screws or other fasteners.

Other systems, methods, features and advantages of the invention will be or will become apparent to one with skill in the art upon examination of the following figures and detailed description.

### BRIEF DESCRIPTION OF THE FIGURES

The details of the invention, including fabrication, structure and operation, may be gleaned in part by study of the accompanying figures, in which like reference numerals refer to like parts. The components in the figures are not necessarily to scale, emphasis instead being placed upon illustrating the principles of the invention. Moreover, all illustrations are intended to convey concepts, where relative sizes, shapes and other detailed attributes may be illustrated schematically rather than literally or precisely.

FIG. 1 is a exploded perspective view of a heat sink and pre-fastened clip assembly in accordance with the present invention.

FIG. 2 is a top view of the clip shown in FIG. 1.

FIG. 3 is a side view of the clip shown in FIG. 1 as viewed from the left of FIG. 2.

FIG. 4 is a front profile view of the clip shown in FIG. 1.

FIG. 5 is a detail view taken along line 5 in FIG. 4.

FIG. 6 is a partial perspective view of a consumer electronic device depicting a heat sink mounted on an integrated circuit board with clips of the present invention shown mounting components requiring heat dissipation.

FIG. 7a is a top view of an alternative embodiment.

FIG. 7b is a plan view of the embodiment shown in FIG. 7a.

### DETAILED DESCRIPTION

The apparatus and methods described herein provide for ease of installation and removal of ICs and other components requiring heat dissipation and mounted on heat sinks in consumer electronic devices. A clip in accordance with the present invention is provided pre-fastened to a heat sink to facilitate the assembly and retention of ICs and other components (referred to generally hereafter as “ICs”) positioned against a heat sink and the removal of the ICs from the heat sink for replacement or servicing.

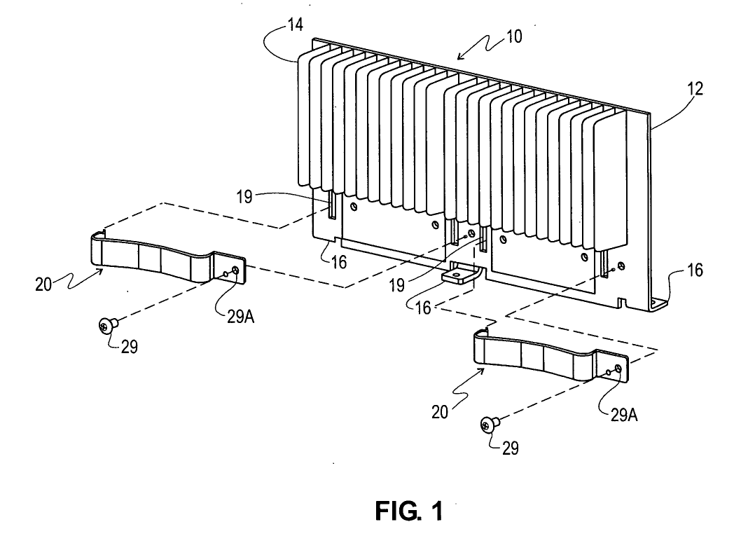

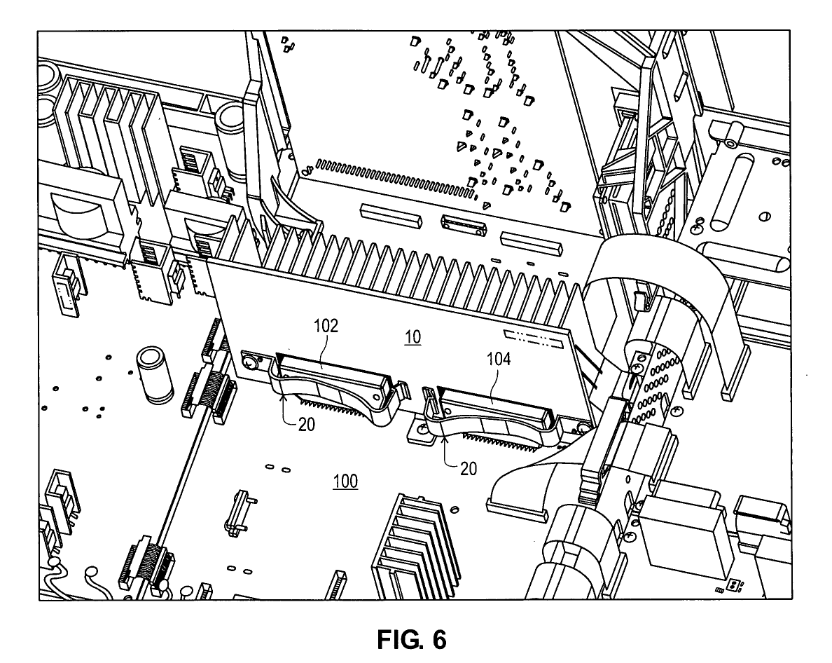

Turning to the figures, FIG. 1 shows a heat sink 10 having a body 12 with cooling fins 14 extending generally orthogonally there from. A series of mounting flanges 16 are provided to mount the heat sink to the chassis or IC board 100 (see FIG. 6) of the consumer electronic device. A pair of clips 20 in accordance with the present invention are shown to be mountable at one end on the heat sink 10 with a screw 29, bolt or other fastener passing through a through hole 29a formed in a mounting base 28 that extends from the body 21 of the clips 20. The screws 29 are received in clip mounting holes 18 formed in the body 12 of the heat sink 10 to pre-fasten the clip 20 to the heat sink 10 prior to assembly.

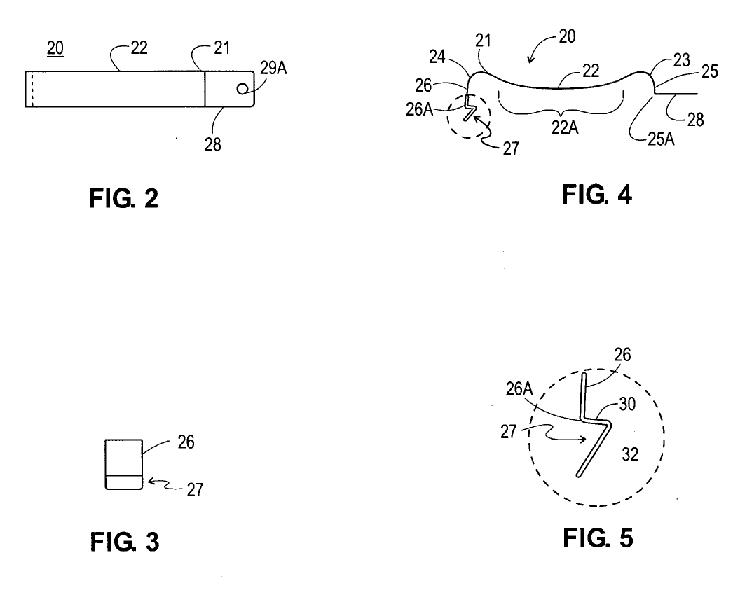

As shown in FIGS. 2 through 5, the clip 20 preferably includes a body 21 having an upper cross-member 22 extending between a fixed leg 25 and a latching leg 26 extending generally orthogonally from the cross-member 22. The cross-member 22 preferably curves inwardly along its central region 22a towards the space between the fixed and latching legs 25 and 26. The intersections 23 and 24 between the fixed leg 25 and cross-member 22 and latching leg 26 and cross-member 22, respectively, are preferably radiused. Extending generally orthogonally outwardly from a base end 25a of the fixed leg 25 is a mounting base 28 used to pre-fasten the clip 20 to the heat sink 10. Extending inwardly from a base end 26a of the latching leg 26, as depicted in greater detail in FIG. 5, is a latch member 27. The latch member 27 preferably includes a recess member 30 extending generally orthogonally from the latching leg 26 and a locking tab 32 extending downwardly from the recess member 30 at a generally outward sloping angle of about 60° measured from an axis defined by the recess member 30.

The clip 10 is preferably formed from steel, half hardness steel, or other metals, plastics, composites, or the like. As shown in FIG. 5, the thickness t of the clip 10 when formed from steel is about 0.5 mm, which facilitates a spring-like quality to the clip 20 to ensure good thermal transfer from the IC to the heat sink 10. One skilled in the art would understand that when formed from other material, the clip 10 must be of a thickness that provides sufficient strength to remain latched and retain the ICs against the heat sink 10 while providing a spring-like quality for ease of installation and removal.

In operation, the clip's mounting base 28 is preferably fastened to the body 12 of the heat sink 10 prior to installation of the heat sink 10 in the consumer electronic device. The heat sink 10 is then fastened to the chassis or IC board 100 of the device (see FIG. 6) and once an IC (e.g., components 102 and 104 in FIG. 6) is positioned against the heat sink 10, the unfastened latching leg 26 of the clip 20 is pushed to deflect it inward to enable the locking tab 32 of the latch member 27 to engage a clip securing slot 19 formed in the body 12 of the heat sink 10. Once the locking tab 32 enters the slot 19, the latch leg 26 is released to allow the locking tab 32 to return to its pre-deflected state and engage the side wall of the slot 19 to releasably lock the clip 20 in place. To release the clip 20 and remove the IC (102, 104) from the heat sink 10, the latching leg 26 is pushed to deflect the locking tab 32 inwards to disengage the latch member 27 from the slot 19.

When the latch member 27 is pressed into a locked orientation with the body 12 of the heat sink 10, the central portion 22a of the cross member 22 exerts a spring force against the IC to ensure good thermal transfer from the IC to the heat sink 10.

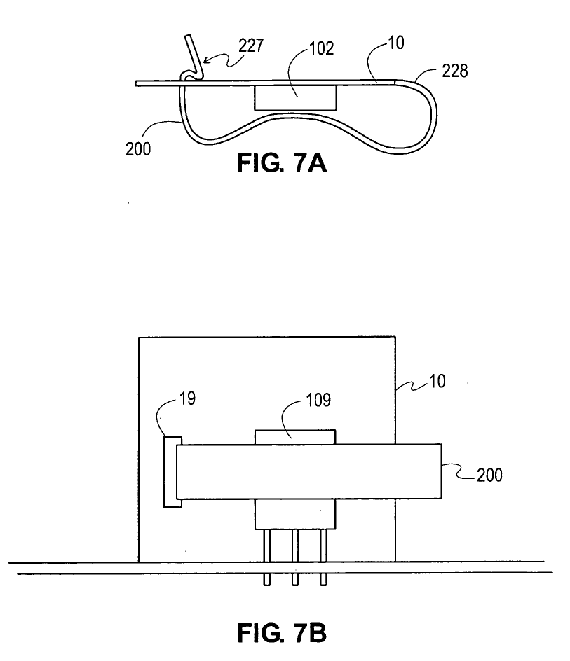

Referring to FIGS. 7a and 7b, an alternative embodiment of the present invention is depicted. As shown, a clip 200 extends at its base end 228 from the body of the heat sink 10 and, preferably, is integrally formed with the heat sink 10 as a unitary heat sink and clip device. The clip 200, like the above described embodiment, includes a latch member 227 that engages a slot 19 formed in the heat sink to retain the IC 102 in place against the heat sink 10 to dissipate heat from the IC 102 to the heat sink. The clip 200 spring-like body may be deflected to engage and disengage the slot 19 of the heat sink.

In the foregoing specification, the invention has been described with reference to specific embodiments thereof. It will, however, be evident that various modifications and changes may be made thereto without departing from the broader spirit and scope of the invention. For example, the reader is to understand that the specific ordering and combination of process actions shown in the process flow diagrams described herein is merely illustrative, unless otherwise stated, and the invention can be performed using different or additional process actions, or a different combination or ordering of process actions. As another example, each feature of one embodiment can be mixed and matched with other features shown in other embodiments. Features and processes known to those of ordinary skill may similarly be incorporated as desired. Additionally and obviously, features may be added or subtracted as desired. Accordingly, the invention is not to be restricted except in light of the attached claims and their equivalents.

What is claimed is:

1. A heat sink comprising
a body, and
a clip for coupling a component needing heat dissipation to the body of the heat sink, the clip including a first end coupled to the body and a second end releasably coupleable to the body.

2. The heat sink of claim 1 wherein the first end of the clip is fastened with a fastener to the body.

3. The heat sink of claim 1 wherein the clip is integrally formed with the body and the first end of the clip extends from the body.

4. The heat sink of claim 1 wherein the clip includes a cross member extending between first and second legs extending from the cross member, the second leg being inwardly deflectable and returnable to a pre-deflected orientation.

5. The heat sink of claim 4 wherein the cross member is curved inwardly toward the space between the first and second legs.

6. The heat sink of claim 4 wherein a first intersection between the cross member and the first leg and a second intersection between the cross member and the second leg, respectively, are formed as a radius.

7. The heat sink of claim 4 wherein the first end of the clip comprises a mounting base extending generally orthogonally from a base end of the first leg.

8. The heat sink of claim 4 wherein the second end of the clip comprises a latch member extending from a base end of the second leg.

9. The heat sink of claim 4 wherein the latch member comprises a recess member extending inwardly from the base end of the second leg and a locking tab extending from the recess member.

10. A mounting clip for a heat sink comprising
a laterally extending cross member,
first and second legs extending generally orthogonal to the cross member
a mounting base extending generally orthogonal to the first leg at an end opposite the cross member, and
a latch member extending from the second leg at an end opposite the cross member, the latch member and second leg being inwardly deflectable and returnable to a pre-deflected position.

11. The clip of claim 10 wherein the cross member is curved inwardly toward the space between the first and second legs.

12. The clip of claim 10 wherein a first intersection between the cross member and the first leg and a second intersection between the cross member and the second leg, respectively, are formed as a radius.

13. The clip of claim 10 wherein the latch member comprises a recess member extending inwardly from the base end of the second leg and a locking tab extending from the recess member.

14. A method of installing a heat sink in a consumer electronic device comprising the steps of
fastening a first end of a mounting clip to a heat sink,
fastening the heat sink to the chassis of the consumer electronic device,
positioning a component needing heat dissipation against the heat sink, and
releasably coupling the second end of the mounting clip to the heat sink fixing the component against the heat sink.

15. The method of claim 14 wherein releasably coupling includes deflecting the second leg of the clip inwardly toward the first leg.

16. The method of claim 15 wherein releasably coupling includes engaging a retaining receptacle in the body of the heat sink with a locking tab extending from the second leg.

17. The method of claim 16 further comprising releasing the second leg and engaging the receptacle of the body of the heat sink with the latch member.

18. The heat sink of claim 17 wherein the clip includes a cross member extending between first and second legs extending from the cross member.

19. The heat sink of claim 18 wherein the cross member is curved inwardly toward the space between the first and second legs.

20. The method of claim 19 further comprising applying a spring force to the component retained by the clip.

21. The clip of claim 20 wherein a first intersection between the cross member and the first leg and a second intersection between the cross member and the second leg, respectively, are formed as a radius.

22. The clip of claim 21 wherein the latch member comprises a recess member extending inwardly from the base end of the second leg and wherein the locking tab extends from the recess member.
